(19) United States
(12) Patent Application Publication
(10) Pub. No.: US 2018/0206334 A1
(43) Pub. Date: Jul. 19, 2018

(54) METAL-LAMINATED STRUCTURE AND HIGH-FREQUENCY DEVICE COMPRISING THE SAME

(71) Applicant: InnoLux Corporation, Miao-Li County (TW)

(72) Inventors: I-Yin LI, Miao-Li County (TW); Chia-Chi HO, Miao-Li County (TW); Yi-Hung LIN, Miao-Li County (TW); Chen-Shuo HSIEH, Miao-Li County (TW); Ker-Yih KAO, Miao-Li County (TW)

(21) Appl. No.: 15/853,517

(22) Filed: Dec. 22, 2017

Related U.S. Application Data
(60) Provisional application No. 62/446,581, filed on Jan. 16, 2017.

(30) Foreign Application Priority Data
Apr. 14, 2017 (CN) 201710245377.7

(51) Int. Cl. H05K 1/02; H05K 3/00; H01Q 1/38

(52) U.S. Cl. CPC H05K 1/0243; H05K 1/0271; H01Q 1/38; H05K 3/0058

(57) ABSTRACT

A metal-laminated structure is provided. The metal-laminated structure includes a substrate, a compressive stress layer disposed on the substrate, and at least one metal layer disposed on the compressive stress layer, wherein the thickness ratio of the metal layer to the compressive stress layer is in a range from 1 to 30. A high-frequency device including the metal-laminated structure is also provided.

### CROSS REFERENCE TO RELATED APPLICATIONS

This application claims the benefit of U.S. Provisional Application No. 62/446,581, filed on Jan. 16, 2017, and China Patent No. 201710245377.7, filed on Apr. 14, 2017, the entireties of which are incorporated by reference herein.

### TECHNICAL FIELD

The technical field relates to a high-frequency device with a metal-laminated structure.

### BACKGROUND

In the fabrication of conventional displays, in general, when a metal layer is deposited on a substrate by a deposition method, for example, PVD, deposition to the thickness of thousands of angstroms is all that is required, and this is consistent with the needs of the product. However, for high-frequency devices (e.g., antennas), it is necessary to provide a thicker metal layer on a substrate. However, for a substrate of conventional thickness, plating of a metal layer having a relatively thick thickness (for example, more than 1 μm) thereon will cause the substrate to warp due to an increase in the internal stress of the structure. Therefore, a substrate plated with metal cannot be successfully conducted into the equipment for subsequent processing such as exposure, development, and the like, and so components with a thick metal layer cannot be fabricated.

Therefore, it is desirable to develop a metal-laminated structure to overcome the above-mentioned problems of warpage caused by fabrication of thick metal layers on the substrate.

### SUMMARY

One embodiment of the disclosure provides a high-frequency device, comprising: a first substrate; a metal-laminated structure opposite to the first substrate, wherein the metal-laminated structure comprises a compressive stress layer disposed on a second substrate, and at least one metal layer disposed on the compressive stress layer, wherein a thickness ratio of the metal layer to the compressive stress layer is in a range from 1 to 30; and a control layer disposed between the first substrate and the metal-laminated structure.

One embodiment of the disclosure provides a metal-laminated structure, comprising: a second substrate; a compressive stress layer disposed on the second substrate; and at least one metal layer disposed on the compressive stress layer, wherein the thickness ratio of the metal layer to the compressive stress layer is in a range from 1 to 30.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 is a cross-sectional view of a high-frequency device in accordance with one embodiment of the disclosure;

FIG. 2 is a cross-sectional view of a metal-laminated structure in accordance with one embodiment of the disclosure;

FIG. 3 is a cross-sectional view of a metal-laminated structure in accordance with one embodiment of the disclosure;

FIG. 4 is a cross-sectional view of a metal-laminated structure in accordance with one embodiment of the disclosure;

FIG. 5 is a cross-sectional view of a metal-laminated structure in accordance with one embodiment of the disclosure;

FIG. 6 is a cross-sectional view of a metal-laminated structure in accordance with one embodiment of the disclosure;

FIG. 7 is a cross-sectional view of a metal-laminated structure in accordance with one embodiment of the disclosure;

FIG. 8 is a cross-sectional view of a metal-laminated structure in accordance with one embodiment of the disclosure;

FIG. 9 shows a comparison of warpage amounts among various metal-laminated structures in accordance with one embodiment of the disclosure;

FIG. 10 shows a comparison of warpage amounts among various metal-laminated structures in accordance with one embodiment of the disclosure;

### DETAILED DESCRIPTION

Hereinafter, some embodiments of the present disclosure will be described in detail. It should be understood that the following description provides many different embodiments or examples for practicing the different patterns of some embodiments of the present disclosure. The specific elements and arrangements described below are merely illustrative of some embodiments of the present disclosure. Of course, these are by way of examples only and not by way of limitations. In addition, repeated labels or marks may be used in different embodiments. These repetitions are merely illustrative of some embodiments of the present disclosure, and do not represent any connection between the various embodiments and/or structures discussed. Furthermore, when a first material layer is said to be located on or above a second material layer, this includes situations where the first material layer is in direct contact with the second material layer, as well as situations where there are one or more other material layers inserted therebetween. In this situation, the first material layer may not be in direct contact with the second material layer.

In addition, relative terms, such as “lower” or “bottom” and “higher” or “top”, may be used in the embodiments to describe the relative relationship of one element to another element in the drawings. It should be understood that if the device in the drawings is turned to upside down, the elements described as being on the “lower” side will become elements on the “higher” side.

Here, the terms “about” and “probably” are usually expressed within 20% of a given value or range, preferably within 10%, and more preferably within 5%, or within 3%, or within 2%, or within 1%, or within 0.5%. Here, the given value is an approximate amount, that is, in the absence of a specific description of “about” and “probably”, it can still imply the meanings of “about” and “probably”.

It should be understood that while various elements, constituent parts, regions, layers, and/or portions may be described herein using the terms “first”, “second”, “third” and the like. However, these elements, constituent parts, regions, layers, and/or portions should not be limited by these terms. Such terms are used merely to distinguish between different elements, constituent parts, regions, layers, and/or portions. Therefore, a first element, constituent part, region, layer, and/or portion discussed below may be referred to as a second element, constituent part, region, layer, and/or portion, without departing from the teachings of some embodiments of the present disclosure.

Unless otherwise defined, all terms (including technical and scientific terms) used herein have the same meaning as commonly understood by a person skilled in the art to which this disclosure belongs. It should be understood that terms such as those defined in commonly used dictionaries should be interpreted to have the same meanings as the related technology and the background or context of the present disclosure, and should not be interpreted in an idealized or excessive formal manner unless specifically defined in the embodiment of the present disclosure.

Certain embodiments of the present disclosure may be understood in conjunction with the drawings, and the drawings of embodiments of the present disclosure are to be regarded as a part of the specification. It should be understood that the drawings of the embodiments of the present disclosure are not plotted as a scale of actual devices and components. The shape and thickness may be exaggerated in the drawings to clearly show the features of the embodiments of the present disclosure. In addition, the structures and devices in the drawings are schematically illustrated in order to clearly show the features of the embodiments of the present disclosure.

In some embodiments of the present disclosure, relative terms such as “lower”, “upper”, “horizontal”, “vertical”, “under”, “above”, “top”, “bottom” and the like should be understood as the orientation shown in the paragraph and the related schema. Such relative terms are for illustrative purposes only and do not mean that the device described thereby is to be manufactured or operated in a particular orientation. With regard to the terms “join” and “connection”, such as “connection”, “interconnection”, etc., unless specifically defined, may refer to the direct contact between the two structures, or the two structures may not be in direct contact with each other, wherein other structures are disposed between the two structures. The terms “join” and “connection” may also include that the two structures are movable, or the two structures are fixed.

It should be noted that the term “substrate” hereinafter may include elements disposed on a transparent substrate and various films overlying the substrate. Above the substrate, any desired transistor element may have been formed. However, in order to simplify the schema, only a flat substrate is shown. In addition, the “substrate surface” includes the film which is located at the top of the transparent substrate and exposed, such as an insulating layer and/or a metal wire.

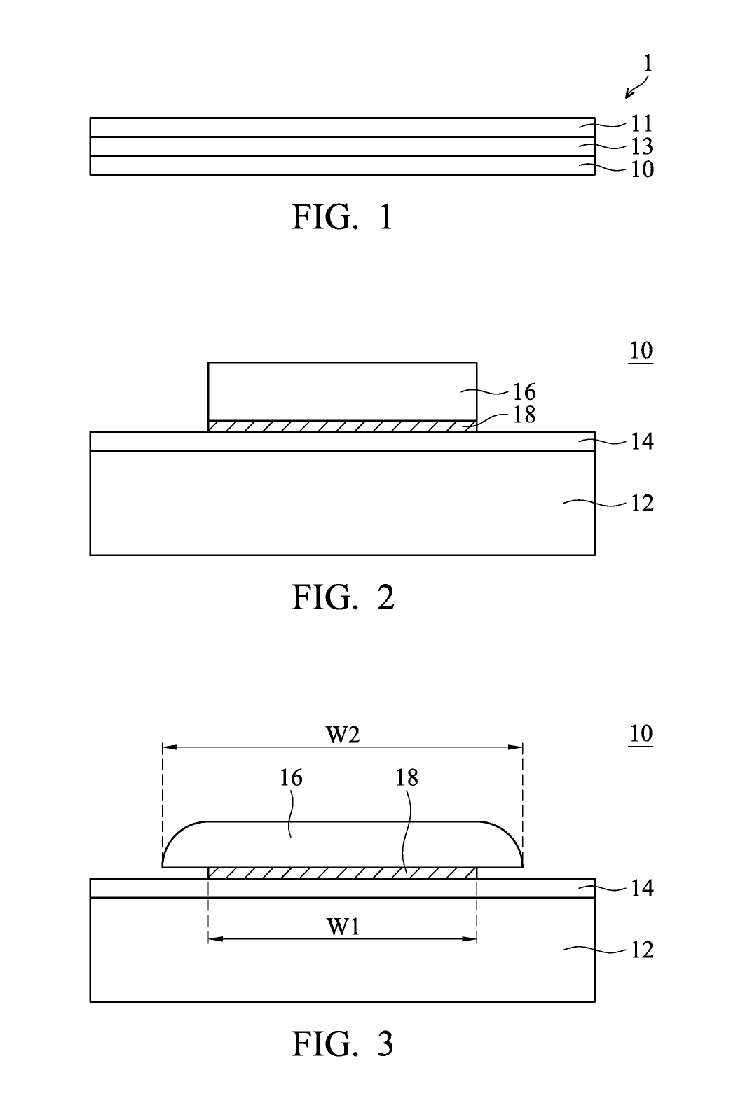

Referring to FIG. 1, in accordance with one embodiment of the disclosure, a high-frequency device 1 is provided. FIG. 1 is a cross-sectional view of the high-frequency device 1.

As shown in FIG. 1, the high-frequency device 1 comprises a metal-laminated structure 10, a first substrate 11 opposite to the metal-laminated structure 10, and a control layer 13 disposed between the metal-laminated structure 10 and the first substrate 11. In one embodiment, the high-frequency device 1 may be an antenna device, such as a liquid-crystal antenna, but is not limited thereto; the metal-laminated structure 10 has a function of transmitting a microwave signal or a waveguide, but is not limited thereto; and the control layer 13 is composed of a material which is capable of controlling beam deflection, such as liquid crystals, but is not limited thereto.

As shown in FIG. 2, the metal-laminated structure 10 comprises a second substrate 12, a compressive stress layer 14 disposed on the second substrate 12, and a metal layer 16 disposed on the compressive stress layer 14. In one embodiment, in the metal-laminated structure 10, the metal layer 16 and the compressive stress layer 14 have a thickness ratio, wherein the thickness ration of the metal layer to the compressive stress layer is in a range from 1 to 30.

In some embodiments, the material used for the second substrate 12 may comprise glass, quartz, sapphire, polycarbonate (PC), polyimide (PI), polyethylene terephthalate (PET), or other materials which are suitable for use as a substrate, but is not limited thereto.

In some embodiments, the thickness of the second substrate 12 is between about 0.1 cm and about 2.0 cm.

In some embodiments, the material of the compressive stress layer 14 may comprise silicon oxide, silicon nitride, silicon oxynitride (SiON), or other material that is suitable as the compressive stress layer, but is not limited thereto.

In some embodiments, the thickness of the compressive stress layer 14 is between about 1,000 Å and about 20,000 Å.

In some embodiments, the material of the metal layer 16 may comprise copper, molybdenum, titanium, aluminum, silver, copper alloy, molybdenum alloy, titanium alloy, aluminum alloy, silver alloy, or a combination thereof, but is not limited thereto.

In this embodiment, the thickness of the metal layer 16 is less than or equal to 20 μm and larger than or equal to 1 μm.

In this embodiment, the thickness ratio of the metal layer 16 to the compressive stress layer 14 is in a range from 1 to 10.

In this embodiment, the metal-laminated structure 10 further comprises an adhesive layer 18 which is formed between the compressive stress layer 14 and the metal layer 16.

In this embodiment, the material of the adhesive layer 18 may comprise molybdenum, titanium, aluminum, copper alloy, molybdenum alloy, indium tin oxide (ITO), indium zinc oxide (IZO), or a combination thereof, but is not limited thereto.

In this embodiment, the thickness of the adhesive layer 18 is between about 50 Å and about 500 Å.

In the disclosure, if the direction of the internal stress of the material (such as a compressive stress direction) is in the opposite direction to the direction of the internal stress of the metal layer (such as a tensile stress direction), such material is suitable for use as the compressive stress layer, for example, silicon oxide, silicon nitride, or silicon oxynitride. In an appearance of a view, after the material layer is disposed on a flat substrate, the central portion of the substrate exhibits upward warping due to the internal stress effect of the material layer, this material layer is defined as the compressive stress material layer.

Additionally, in this embodiment, the metal layer in the metal-laminated structure 10 is a single-layered structure (including the metal layer 16). In order to increase the adhesion between the metal layer and the compressive stress layer, the adhesive layer 18 made of, for example, molybdenum metal is disposed between the compressive stress layer 14 and the metal layer 16.

Referring to FIG. 3, in accordance with one embodiment of the disclosure, a metal-laminated structure 10 is provided. FIG. 3 is a cross-sectional view of the metal-laminated structure 10. The embodiment of FIG. 3 is substantially similar to the embodiment of FIG. 2 described above, and therefore, the description thereof will not be repeated.

As shown in FIG. 3, the main difference from the embodiment of FIG. 2 described above is that, in this embodiment, the sidewall of the metal layer 16 is curved, and the metal layer 16 has a width W2 which is larger than a width W1 of the adhesive layer 18.

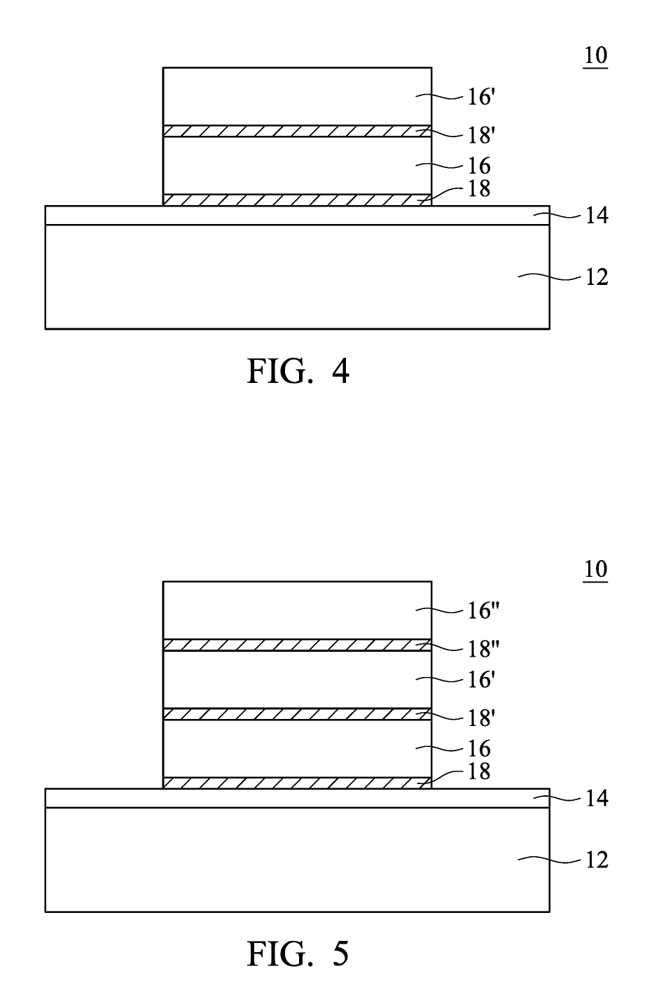

Referring to FIG. 4, in accordance with one embodiment of the disclosure, a metal-laminated structure 10 is provided. FIG. 4 is a cross-sectional view of the metal-laminated structure 10.

As shown in FIG. 4, the metal-laminated structure 10 comprises a second substrate 12, a compressive stress layer 14 disposed on the second substrate 12, a first metal layer 16 disposed on the compressive stress layer 14, and a second metal layer 16′ disposed on the first metal layer 16. In one embodiment, in the metal-laminated structure 10, a thickness ration of the first metal layer 16 to the compressive stress layer 14 is in a range from 1 to 30 (less than or equal to about 30 and larger than or equal to about 1). The second metal layer 16′ and the compressive stress layer 14 have a thickness ratio, wherein the thickness ratio of the second metal layer 16′ to the compressive stress layer 14 is in a range from 1 to 30.

In some embodiments, the material used for the second substrate 12 may comprise glass, quartz, sapphire, polycarbonate (PC), polyimide (PI), polyethylene terephthalate (PET), or other materials which are suitable for use as a substrate, but is not limited thereto.

In some embodiments, the thickness of the second substrate 12 is between about 0.1 cm and about 2.0 cm.

In some embodiments, the material of the compressive stress layer 14 may comprise silicon oxide, silicon nitride, silicon oxynitride (SiON), or other material that is suitable as the compressive stress layer, but is not limited thereto.

In some embodiments, the thickness of the compressive stress layer 14 is between about 1,000 Å and about 20,000 Å.

In some embodiments, the material of the first metal layer 16 and the second metal layer 16′ may comprise copper, molybdenum, titanium, aluminum, silver, copper alloy, molybdenum alloy, titanium alloy, aluminum alloy, silver alloy, or a combination thereof, but is not limited thereto.

In this embodiment, the thickness of the first metal layer 16 is less than or equal to 20 μm and larger than or equal to 1 μm.

In this embodiment, the thickness of the second metal layer 16′ is less than or equal to 20 μm and larger than or equal to 1 μm.

In this embodiment, the thickness ratio of the first metal layer 16 to the compressive stress layer 14 is in a range from 1 to 6.

In this embodiment, the thickness ratio of the second metal layer 16′ to the compressive stress layer 14 is in a range from 1 to 6.

In this embodiment, the metal-laminated structure 10 further comprises a first adhesive layer 18 which is formed between the compressive stress layer 14 and the first metal layer 16.

In this embodiment, the material which is used for the first adhesive layer 18 may comprise molybdenum, titanium, aluminum, copper alloy, molybdenum alloy, indium tin oxide (ITO), indium zinc oxide (IZO), or a combination thereof, but is not limited thereto.

In this embodiment, the thickness of the first adhesive layer 18 is between about 50 Å and about 500 Å.

In this embodiment, the metal-laminated structure 10 further comprises a second adhesive layer 18′ which is formed between the first metal layer 16 and the second metal layer 16′.

In this embodiment, the material which is used for the second adhesive layer 18′ may comprise molybdenum, titanium, aluminum, copper alloy, molybdenum alloy, indium tin oxide (ITO), indium zinc oxide (IZO), or a combination thereof, but is not limited thereto.

In this embodiment, the thickness of the second adhesive layer 18′ is between about 50 Å and about 500 Å.

In this embodiment, the metal layer in the metal-laminated structure 10 is a multiple-layered structure (including the first metal layer 16 and the second metal layer 16′). In order to increase the adhesion between the metal layer and the compressive stress layer and the adhesion between the metal layers, the first adhesive layer 18 which is made of, for example, molybdenum metal is disposed between the compressive stress layer 14 and the first metal layer 16. The second adhesive layer 18′ which is made of, for example, molybdenum metal is disposed between the first metal layer 16 and the second metal layer 16′.

Referring to FIG. 5, in accordance with one embodiment of the disclosure, a metal-laminated structure 10 is provided. FIG. 5 is a cross-sectional view of the metal-laminated structure 10.

As shown in FIG. 5, the metal-laminated structure 10 comprises a second substrate 12, a compressive stress layer 14 disposed on the second substrate 12, a first metal layer 16 disposed on the compressive stress layer 14, a second metal layer 16′ disposed on the first metal layer 16, and a third metal layer 16″ disposed on the second metal layer 16′. In one embodiment, in the metal-laminated structure 10, the first metal layer 16 and the compressive stress layer 14 have a thickness ratio, wherein the thickness ratio of the first metal layer 16 to the compressive stress layer 14 is in a range from 1 to 30. The second metal layer 16′ and the compressive stress layer 14 have a thickness ratio, wherein the thickness ratio of the second metal later 16′ to the compressive stress layer 14 is in a range from 1 to 30. In addition, the third metal layer 16″ and the compressive stress layer 14 have a thickness ratio, wherein the thickness ratio of the third metal layer 16″ to the compressive stress layer is in a range from 1 to 30.

In some embodiments, the material used for the second substrate 12 may comprise glass, quartz, sapphire, polycarbonate (PC), polyimide (PI), polyethylene terephthalate (PET), or other materials which are suitable for use as a substrate, but is not limited thereto.

In some embodiments, the thickness of the second substrate 12 is between about 0.1 cm and about 2.0 cm.

In some embodiments, the material of the compressive stress layer 14 may comprise silicon oxide, silicon nitride, silicon oxynitride (SiON), or other material that is suitable as the compressive stress layer, but is not limited thereto.

In some embodiments, the thickness of the compressive stress layer 14 is between about 1,000 Å and about 20,000 Å.

In some embodiments, the material of the first metal layer 16, the second metal layer 16′, and the third metal layer 16″ may comprise copper, molybdenum, titanium, aluminum, silver, copper alloy, molybdenum alloy, titanium alloy, aluminum alloy, silver alloy, or a combination thereof, but is not limited thereto.

In this embodiment, the thickness of the first metal layer 16 is less than or equal to 20 μm and larger than or equal to 1 μm.

In this embodiment, the thickness of the second metal layer 16′ is less than or equal to 20 μm and larger than or equal to 1 μm.

In this embodiment, the thickness of the third metal layer 16″ is less than or equal to 20 μm and larger than or equal to 1 μm.

In this embodiment, the thickness ratio of the first metal layer 16 to the compressive stress layer 14 is in a range from 1 to 4.

In this embodiment, the thickness ratio of the second metal layer 16′ to the compressive stress layer 14 is in a range from 1 to 4.

In this embodiment, the thickness ratio of the third metal layer 16″ to the compressive stress layer 14 is in a range from 1 to 4.

In this embodiment, the metal-laminated structure 10 further comprises a first adhesive layer 18 which is formed between the compressive stress layer 14 and the first metal layer 16.

In this embodiment, the material which is used for the first adhesive layer 18 may comprise molybdenum, titanium, aluminum, copper alloy, molybdenum alloy, indium tin oxide (ITO), indium zinc oxide (IZO), or a combination thereof, but is not limited thereto.

In this embodiment, the thickness of the first adhesive layer 18 is between about 50 Å and about 500 Å.

In this embodiment, the metal-laminated structure 10 further comprises a second adhesive layer 18′ which is formed between the first metal layer 16 and the second metal layer 16′.

In this embodiment, the material which is used for the second adhesive layer 18′ may comprise molybdenum, titanium, aluminum, copper alloy, molybdenum alloy, indium tin oxide (ITO), indium zinc oxide (IZO), or a combination thereof, but is not limited thereto.

In this embodiment, the thickness of the second adhesive layer 18′ is between about 50 Å and about 500 Å.

In this embodiment, the metal-laminated structure 10 further comprises a third adhesive layer 18″ which is formed between the second metal layer 16′ and the third metal layer 16″.

In this embodiment, the material which is used for the third adhesive layer 18″ may comprise molybdenum, titanium, aluminum, copper alloy, molybdenum alloy, indium tin oxide (ITO), indium zinc oxide (IZO), or a combination thereof, but is not limited thereto.

In this embodiment, the thickness of the third adhesive layer 18″ is between about 50 Å and about 500 Å.

In this embodiment, the metal layer in the metal-laminated structure 10 is a multiple-layered structure (including the first metal layer 16, the second metal layer 16′, and the third metal layer 16″). In order to increase the adhesion between the metal layer and the compressive stress layer and the adhesion between the metal layers, the first adhesive layer 18 which is made of, for example, molybdenum metal is disposed between the compressive stress layer 14 and the first metal layer 16. The second adhesive layer 18′ which is made of, for example, molybdenum metal is disposed between the first metal layer 16 and the second metal layer 16′. The third adhesive layer 18″ which is made of, for example, molybdenum metal is disposed between the second metal layer 16′ and the third metal layer 16″.

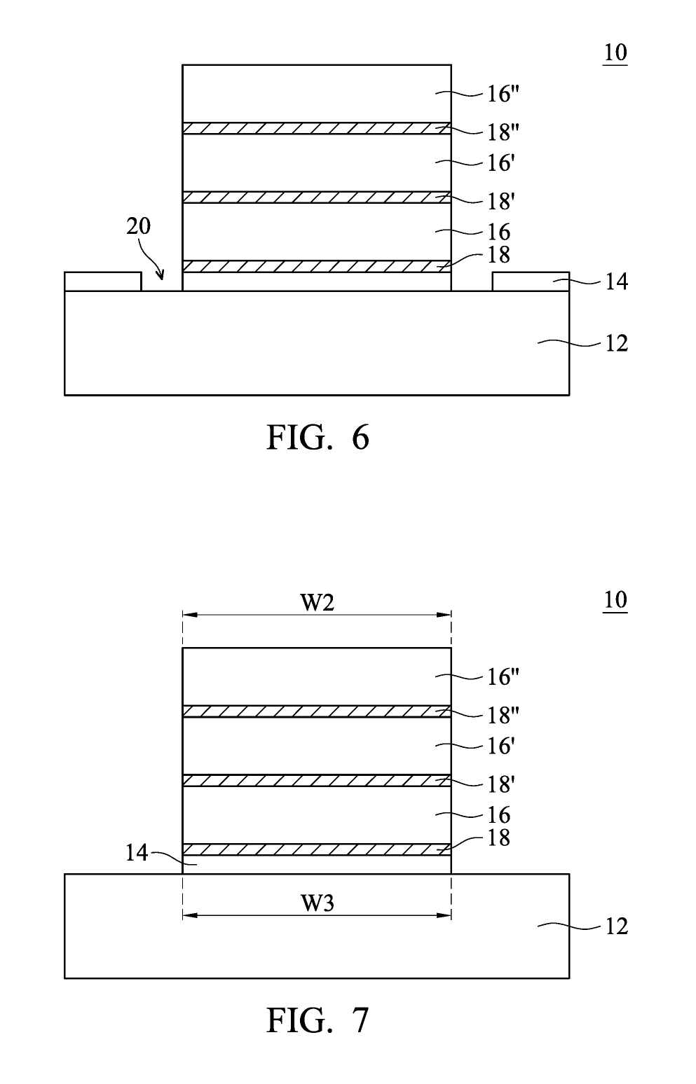

Referring to FIG. 6, in accordance with one embodiment of the disclosure, a metal-laminated structure 10 is provided. FIG. 6 is a cross-sectional view of the metal-laminated structure 10. The embodiment of FIG. 6 is substantially similar to the embodiment of FIG. 5 described above, and therefore, the description thereof will not be repeated.

As shown in FIG. 6, the main difference from the embodiment of FIG. 5 described above is that, in this embodiment, the compressive stress layer 14 further comprises a plurality of openings 20 formed therein to effectively release various internal stresses produced in the metal-laminated structure 10.

Referring to FIG. 7, in accordance with one embodiment of the disclosure, a metal-laminated structure 10 is provided. FIG. 7 is a cross-sectional view of the metal-laminated structure 10. The embodiment of FIG. 7 is substantially similar to the embodiment of FIG. 5 described above, and therefore, the description thereof will not be repeated.

As shown in FIG. 7, the main difference from the embodiment of FIG. 5 described above is that, in this embodiment, the width W3 of the compressive stress layer 14 is made to be the same as the width W2 of the first metal layer 16, the second metal layer 16′, and the third metal layer 16″ to effectively release various internal stresses produced in the metal-laminated structure 10.

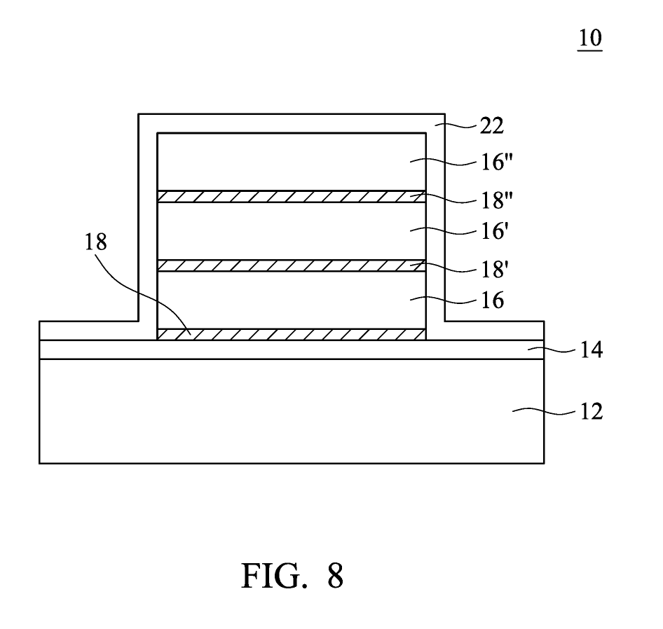

Referring to FIG. 8, in accordance with one embodiment of the disclosure, a metal-laminated structure 10 is provided. FIG. 8 is a cross-sectional view of the metal-laminated structure 10. The embodiment of FIG. 8 is substantially similar to the embodiment of FIG. 5 described above, and therefore, the description thereof will not be repeated.

As shown in FIG. 8, the main difference from the embodiment of FIG. 5 described above is that, in this embodiment, the metal-laminated structure 10 further comprises a second compressive stress layer 22 disposed on the third metal layer 16″ and the compressive stress layer 14 to effectively release various internal stresses produced in the metal-laminated structure 10.

### EXAMPLES

### Example 1

Comparison of Warpage Amounts Among Various Metal-Laminated Structures

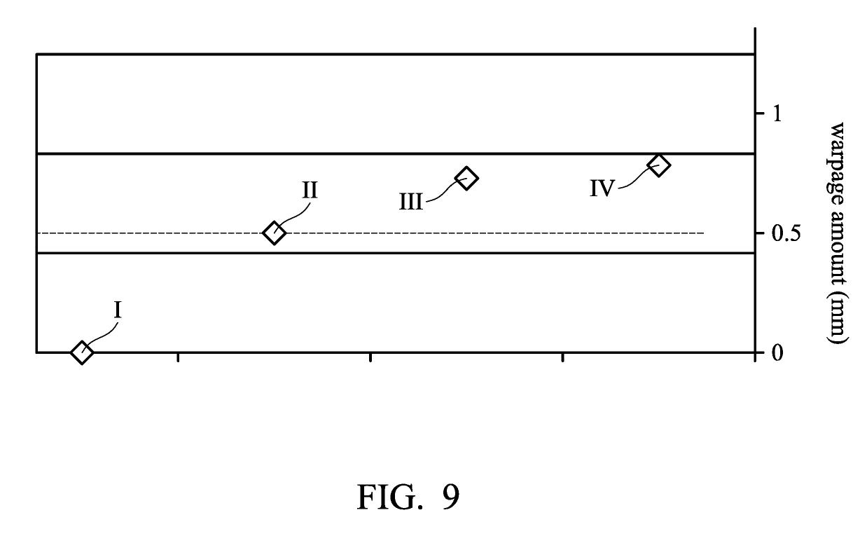

In this example, the warpage amounts among various metal-laminated structures are compared. Various metal-laminated structures (including structure (I), structure (II), structure (III), and structure (IV)) were selected, and the warpage amount of each structure was measured. The warpage amount is defined as a perpendicular distance from the center of the substrate to the warped edge thereof. The measurement results are shown in FIG. 9. FIG. 9 shows the warpage amounts generated in various metal-laminated structures (including structure (I), structure (II), structure (III), and structure (IV)). The composition of each structure is described as follows.

The composition of structure (I): A glass substrate with thickness of about 0.5 mm.

The composition of structure (II): A non-patterned molybdenum layer (about 100 Å) and a non-patterned copper layer (about 1 μm) disposed on the glass substrate in order.

The composition of structure (III): A patterned first molybdenum layer (about 100 Å) and a patterned first copper layer (about 1 μm), and a non-patterned second molybdenum layer (about 100 Å) and a non-patterned second copper layer (about 1 μm) disposed on the glass substrate in order.

The composition of structure (IV): A patterned first molybdenum layer (about 100 Å) and a patterned first copper layer (about 1 μm), a patterned second molybdenum layer (about 100 Å) and a patterned second copper layer (about 1 μm), and a non-patterned third molybdenum layer (about 100 Å) and a non-patterned third copper layer (about 1 μm) disposed on the glass substrate in order.

From FIG. 9, it can be seen that when the upper limit of the allowable warpage of the substrate is set to 0.5mm by the equipment machine, the amount of warpage variation of, for example, structure (III) and structure (IV) has exceeded the allowable range of the equipment machine. It is apparent that it is unable to provide a substrate on which a thick copper layer (for example, thickness of up to 1 μm or more) may perform subsequent operations, such as exposure, development, and the like, under the current conditions of the equipment machine.

### Example 2

Comparison of warpage amounts among various metal-laminated structures

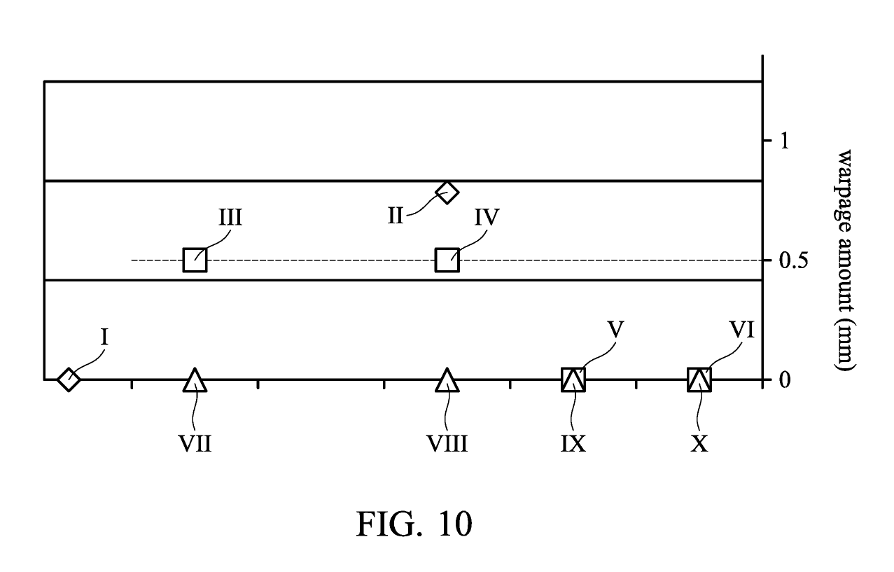

In this example, the warpage amounts among various metal-laminated structures are compared. Various metal-laminated structures (including structure (I), structure (II), structure (III), structure (IV), structure (V), structure (VI), structure (VII), structure (VIII), structure (IX), and structure (X)) were selected, and the warpage amount of each structure was measured. The warpage amount is defined as a perpendicular distance from the center of the substrate to the warped edge thereof. The measurement results are shown in FIG. 10. FIG. 10 shows the warpage amounts generated in various metal-laminated structures (including structure (I), structure (II), structure (III), structure (IV), structure (V), structure (VI), structure (VII), structure (VIII), structure (IX), and structure (X)). The composition of each structure is described as follows.

The composition of structure (I): A glass substrate with thickness of about 0.5 mm.

The composition of structure (II): A patterned first molybdenum layer (about 100 Å) and a patterned first copper layer (about 1 μm), a patterned second molybdenum layer (about 100 Å) and a patterned second copper layer (about 1 μm), and a non-patterned third molybdenum layer (about 100 Å) and a non-patterned third copper layer (about 1 μm) disposed on the glass substrate in order.

The composition of structure (III): A first silicon nitride compressive stress layer (about 5,000 Å), and a non-patterned molybdenum layer (about 100 Å) and a non-patterned copper layer (about 1 μm) disposed on the glass substrate in order.

The composition of structure (IV): A first silicon nitride compressive stress layer (about 5,000 Å), a patterned first molybdenum layer (about 100 Å) and a patterned first copper layer (about 1 μm), a patterned second molybdenum layer (about 100 Å) and a patterned second copper layer (about 1 μm), and a non-patterned third molybdenum layer (about 100 Å) and a non-patterned third copper layer (about 1 μm) disposed on the glass substrate in order.

The composition of structure (V): A first silicon nitride compressive stress layer (about 5,000 Å), a patterned first molybdenum layer (about 100 Å) and a patterned first copper layer (about 1 μm), a patterned second molybdenum layer (about 100 Å) and a patterned second copper layer (about 1 μm), a patterned third molybdenum layer (about 100 Å) and a patterned third copper layer (about 1 μm), and the first silicon nitride compressive stress layer (about 1,000 Å) disposed on the glass substrate in order.

The composition of structure (VI): A first silicon nitride compressive stress layer (about 5,000 Å), a patterned first molybdenum layer (about 100 Å) and a patterned first copper layer (about 1 μm), a patterned second molybdenum layer (about 100 Å) and a patterned second copper layer (about 1 μm), a patterned third molybdenum layer (about 100 Å) and a patterned third copper layer (about 1 μm), and the first silicon nitride compressive stress layer (about 5,000 Å) disposed on the glass substrate in order.

The composition of structure (VII): A first silicon nitride compressive stress layer (about 5,000 Å), and a non-patterned molybdenum layer (about 100 Å) and a non-patterned copper layer (about 1 μm) disposed on the glass substrate in order.

The composition of structure (VIII): A first silicon nitride compressive stress layer (about 5,000 Å), a patterned first molybdenum layer (about 100 Å) and a patterned first copper layer (about 1 μm), a patterned second molybdenum layer (about 100 Å) and a patterned second copper layer (about 1 μm), and a non-patterned third molybdenum layer (about 100 Å) and a non-patterned third copper layer (about 1 μm) disposed on the glass substrate in order.

The composition of structure (IX): A first silicon nitride compressive stress layer (about 5,000 Å), a patterned first molybdenum layer (about 100 Å) and a patterned first copper layer (about 1 μm), a patterned second molybdenum layer (about 100 Å) and a patterned second copper layer (about 1 μm), a patterned third molybdenum layer (about 100 Å) and a patterned third copper layer (about 1 μm), and the second silicon nitride compressive stress layer (about 1,000 Å) disposed on the glass substrate in order.

The composition of structure (X): A first silicon nitride compressive stress layer (about 5,000 Å), a patterned first molybdenum layer (about 100 Å) and a patterned first copper layer (about 1 μm), a patterned second molybdenum layer (about 100 Å) and a patterned second copper layer (about 1 μm), a patterned third molybdenum layer (about 100 Å) and a patterned third copper layer (about 1 μm), and the second silicon nitride compressive stress layer (about 5,000 Å) disposed on the glass substrate in order.

The distinction between the first silicon nitride compressive stress layer and the second silicon nitride compressive stress layer is that the internal stress generated in the layers is different. For example, by adjusting the parameters such as gas ratio, flow rate, film-forming power, pressure, etc., the first silicon nitride compressive stress layer and the second silicon nitride compressive stress layer having different internal stress therebetween are obtained.

From FIG. 10, it can be seen that when the upper limit of the allowable warpage of the substrate is set to 0.5 mm by the equipment machine, all the amount of warpage variations of the structures in which the compressive stress layer is disposed (including structure (III), structure (IV), structure (V), structure (VI), structure (VII), structure (VIII), structure (IX), and structure (X)) of the present disclosure fall within the allowable range of the equipment machine, and even, a part of the substrate structures can maintain no warping phenomenon (i.e. the warpage amount thereof is zero). It is apparent that although the substrate is coated with a thick copper layer (for example, up to 10,000 Å or more) thereon in the present disclosure, due to disposition of the compressive stress layer which is effectively able to offset the warpage of the copper layer in the structures (ex. located above the thick copper layer and/or below the thick copper layer), it is possible to smoothly introduce such substrate structures into the current equipment machine for subsequent processing such as exposure, development and the like.

In the present disclosure, before the metal layer is plated on the substrate, the compressive stress layer composed of, for example, silicon oxide, silicon nitride, or silicon oxynitride having an internal stress opposite to that of the copper layer (i.e. a tensile stress layer) is plated on the substrate, and/or after the metal layer is plated on the substrate, the compressive stress layer is further plated on the metal layer such that the warping phenomenon caused by plating of the metal layer can be effectively improved by disposition of the above-mentioned compressive stress layer. In addition, in the present disclosure, the internal stress in the structure can also be effectively released by performing a patterning process on the metal layer, resulting in reduced warpage. During the processes, after the lower metal layer is patterned, another metal layer is stacked thereon, and then, the other metal layer is patterned to timely release the internal stress generated by another metal layer. Finally, a stack of multiple metal layers is completed in this manner. On one hand, a metal layer of the required thickness (for example, more than 1 micron) is fabricated. On the other hand, due to the internal stress in the structure being timely released during the processes, the possibility of warpage of the substrate structure can also be significantly reduced. The technology provided by the present disclosure can be widely used in various industries which demand a thick metal layer and a large-sized substrate.

It will be apparent to those skilled in the art that various modifications and variations can be made to the disclosed embodiments. It is intended that the specification and examples be considered as exemplary only, with the true scope of the disclosure being indicated by the following claims and their equivalents.

What is claimed is:

1. A high-frequency device, comprising:
a first substrate;
a metal-laminated structure opposite to the first substrate, wherein the metal-laminated structure comprises a compressive stress layer disposed on a second substrate, and at least one metal layer disposed on the compressive stress layer, wherein a thickness ratio of the metal layer to the compressive stress layer is in a range from 1 to 30; and
a control layer disposed between the first substrate and the metal-laminated structure.

2. The high-frequency device as claimed in claim 1, wherein the compressive stress layer comprises silicon oxide, silicon nitride, or silicon oxynitride.

3. The high-frequency device as claimed in claim 1, wherein the metal layer comprises copper.

4. The high-frequency device as claimed in claim 1, wherein a thickness of the metal layer is less than or equal to 20 μm and larger than or equal to 1 μm.

5. The high-frequency device as claimed in claim 1, wherein the thickness ratio of the metal layer to the compressive stress layer is in a range from 1 to 10.

6. The high-frequency device as claimed in claim 1, further comprising an adhesive layer formed between the compressive stress layer and the metal layer.

7. The high-frequency device as claimed in claim 6, wherein the adhesive layer comprises molybdenum, titanium, aluminum, copper alloy, molybdenum alloy,

8. The high-frequency device as claimed in claim 6, wherein a width of the metal layer is larger than that of the adhesive layer.

9. The high-frequency device as claimed in claim 1, wherein the compressive stress layer further comprises a plurality of openings therein.

10. The high-frequency device as claimed in claim 1, wherein a width of the compress stress layer is larger than or equal to that of the metal layer.

11. A metal-laminated structure, comprising:
a substrate;
a compressive stress layer disposed on the substrate; and
at least one metal layer disposed on the compressive stress layer, wherein a thickness ratio of the metal layer to the compressive stress layer is in a range from 1 to 30.

12. The metal-laminated structure as claimed in claim 11, wherein the compressive stress layer comprises silicon oxide, silicon nitride, or silicon oxynitride.

13. The metal-laminated structure as claimed in claim 11, wherein the metal layer comprises copper.

14. The metal-laminated structure as claimed in claim 11, a thickness of the metal layer is less than or equal to 20 μm and larger than or equal to 1 μm.

15. The metal-laminated structure as claimed in claim 11, wherein the thickness ratio of the metal layer to the compressive stress layer is in a range from 1 to 10.

16. The metal-laminated structure as claimed in claim 11, further comprising an adhesive layer formed between the compressive stress layer and the metal layer.

17. The metal-laminated structure as claimed in claim 16, wherein the adhesive layer comprises molybdenum, titanium, aluminum, copper alloy, molybdenum alloy, indium tin oxide (ITO), indium zinc oxide (IZO), or a combination thereof.

18. The metal-laminated structure as claimed in claim 16, wherein a width of the metal layer is larger than that of the adhesive layer.

19. The metal-laminated structure as claimed in claim 11, wherein the compressive stress layer further comprises a plurality of openings therein.

20. The metal-laminated structure as claimed in claim 11, wherein a width of the compressive stress layer is larger than or equal to that of the metal layer.
